(19) United States
(12) Patent Application Publication
(10) Pub. No.: US 2019/0198448 A1
(43) Pub. Date: Jun. 27, 2019

(54) ANISOTROPICALLY CONDUCTIVE ELASTIC ADHESIVE FILMS IN SEMICONDUCTOR DEVICE PACKAGES AND METHODS OF ASSEMBLING SAME

(71) Applicant: Intel IP Corporation, Santa Clara, CA (US)

(72) Inventors: Sonja Koller, Regensburg (DE); Georg Seidemann, Landshut (DE); Bernd Waidhas, Pettendorf (DE)

(21) Appl. No.: 15/852,908

(22) Filed: Dec. 22, 2017

(51) Int. Cl. H01L 23/538; H01L 23/367; H01L 23/552; H01L 23/498; H01L 23/373; H01L 23/00; H01L 25/00

(52) U.S. Cl. CPC H01L 23/5387; H01L 23/3675; H01L 23/552; H01L 23/5385; H01L 23/49833; H01L 23/481; H01L 24/32; H01L 24/83; H01L 25/50; H01L 23/49816; H01L 23/3733

(57) ABSTRACT

A semiconductor device package includes an anisotropically conductive flexible film including a plurality of electrically conductive corridors. The film is coupled to make electronic and also heat-transfer contact to a semiconductive device.

### FIELD

This disclosure relates to anisotropically conductive elastic adhesive films that assist in assembly of semiconductor device packages.

### BACKGROUND

Semiconductive device miniaturization during packaging includes challenges to locate several semiconductive devices as well as passive devices in close proximity and to occupy a small overall footprint.

### BRIEF DESCRIPTION OF THE DRAWINGS

Disclosed embodiments are illustrated by way of example, and not by way of limitation, in the figures of the accompanying drawings where like reference numerals may refer to similar elements, in which:

FIG. 1A is a cross-section elevation of an anisotropically conductive flexible film that includes a plurality of electrically conductive channels according to an embodiment;

FIG. 1B is a cross-section elevation of the anisotropically conductive flexible film depicted in FIG. 1A as applied to a semiconductor device package according to an embodiment;

FIG. 2A is a cross-section elevation of a flexible film that includes a dispersion of electrically conductive particles according to an embodiment;

FIG. 2B is a cross-section elevation of a semiconductor device package that includes the flexible film depicted in FIG. 2A according to an embodiment;

FIG. 3 is a cross-section elevation of a semiconductor device package that includes an anisotropically conductive flexible film with anisotropic electrical and heat conductivities according to an embodiment;

FIG. 3A is a cross-section elevation of a portion of the semiconductor device package depicted in FIG. 3 during assembly according to an embodiment;

FIG. 4 is a cross-section elevation of a semiconductor device package that includes an anisotropically conductive flexible film with anisotropic electrical and heat conductivities according to an embodiment;

FIG. 5 is a cross-section elevation of a semiconductor device package that includes an anisotropically conductive flexible film with anisotropic electrical and heat conductivities according to an embodiment;

FIG. 6 is a cross-section elevation of a semiconductor device package that includes an anisotropically conductive flexible film with anisotropic electrical and heat conductivities according to an embodiment;

FIG. 7 is a cross-section elevation of a semiconductor devise package on-package that includes anisotropically conductive flexible films with anisotropic electrical and heat conductivities according to an embodiment;

FIG. 8 is a cross-section elevation of a semiconductor device package that includes a flexible film with anisotropic electrical and heat conductivities according to an embodiment;

FIG. 9 is a cross-section elevation of a semiconductor device package that includes an anisotropically conductive flexible film that couples with a ribbon interconnect according to an embodiment;

FIG. 10 is a process flow diagram for assembling a semiconductor device package according to several embodiments; and

FIG. 11 is included to show an example of a higher-level device application for the disclosed embodiments.

### DETAILED DESCRIPTION

Elastic heat-transfer films include anisotropic electrical conductivity corridors that function for heat transfer channels as well as possibly for signal- and power/ground channels. The anisotropically conductive flexible films are installed where head space may have been found, but electrical and heat-conduction connections are established between respective other devices and heat sinks.

FIG. 1A is a cross-section elevation 101 of an anisotropically conductive flexible film 110 that includes a plurality of electrically conductive channels 112 according to an embodiment. The anisotropically conductive flexible film 110 includes an elastic body 110 and a plurality of electrically conductive channels, one instance of which is indicated with reference numeral 112. In an embodiment, the elastic body 110 is made from a silicone polymer that allows for flexibility, compressibility, but it retains sufficient structural cohesion that the several electrically conductive channels 112 do not short into each other during compression.

In an embodiment, the several conductive channels 112 are made from electronics-grade copper (Cu) and consequently, the conductive channels 112 provide useful anisotropic heat and electrical conductivity where the anisotropically conductive flexible film 101 is applied to convey excess heat away from an electronic semiconductive device.

FIG. 1B is a cross-section elevation of the anisotropically conductive flexible film 110 depicted in FIG. 1A as applied to a semiconductor device package 102 according to an embodiment. The anisotropically conductive flexible film 110 is under focused compression from a first semiconductive device 116 and a subsequent semiconductive device 120. Focused compression regions create a flexible film with anisotropic electrical conductivity, and focused compression is provided between bond pads 118 and 122, and between bond pads 118′ and 122′, such that electrical connections are made between the first semiconductive device 116 and the subsequent semiconductive device 120.

A region in the anisotropically conductive flexible film that is between adjacent bond pads 118 and 118′ and between adjacent bond pads 122 and 122′, however, has no electrical connection between the first semiconductive device 116 and the subsequent semiconductive device 120. Accordingly, a given compressive embodiment of the anisotropically conductive flexible film 110 is useful for anisotropic electrical conductivity.

As illustrated in FIG. 1A, the anisotropically conductive flexible film 110 has a rest thickness 114 (measured in the Z-direction), and as illustrated in FIG. 1B, the anisotropically conductive flexible film 110 has a compressed thickness 115 that is less than the rest thickness 114, where electrical interconnections are made between the two devices 116 and 120. As configured, the anisotropically conductive flexible film 110 is a conductive and electronically connective bridge 110 between a bottom semiconductive device 116 and a top semiconductive device 120.

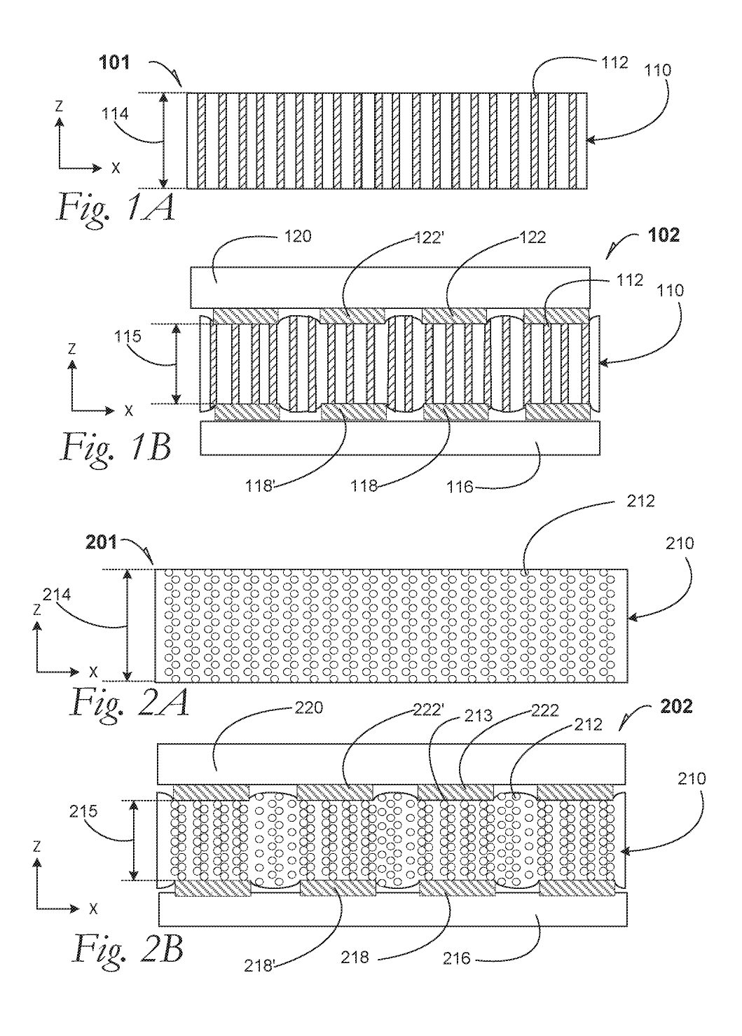

FIG. 2A is a cross-section elevation 201 of a flexible film 210 that includes a dispersion of electrically conductive particles 212 according to an embodiment. The flexible film 210 includes an elastic body 210 and a dispersion of electrically conductive particles, one instance of which is indicated with reference numeral 212. In an embodiment, the elastic body 210 is made from a silicone polymer that allows for flexibility such as compressibility, but it retains sufficient structural cohesion that the dispersion of electrically, conductive particles 212 do not laterally short into each other during e.g. compression, but under useful compression, sufficient inter-particle electrical contact is made to create an electrically conductive channel.

In an embodiment, the dispersion of electrically conductive particles 212 is made from electronics-grade copper (Cu) particles, and consequently the dispersion 212 provides useful heat conductivity where the anisotropically conductive flexible film 210 is applied to convey excess heat away from an electronic semiconductive device.

FIG. 2B is a cross-section elevation of a semiconductor device package 202 that includes the flexible film 210 depicted in FIG. 2A according to an embodiment. The flexible film 210 is under compression from a first semiconductive device 216 and a subsequent semiconductive device 220. Focused compression is provided between bond pads 218 and 222, and between bond pads 218′ and 222′, such that virtual anisotropic interconnects 213 are formed where regional dispersions of electrically conductive particles are sufficiently compressed. The virtual anisotropic interconnects are present, one of which is depicted with reference numeral 213. The focused compression regions create an anisotropically conductive flexible film 210 with anisotropic electrical conductivity. A region in the anisotropically conductive flexible film that is between adjacent bond pads 218 and 218′, and adjacent bond pads 222 and 222′, has no electrical connection among the uncompressed dispersion of electrically conductive particles 212, because compression of the anisotropically conductive flexible film 210, if any in this region, does not created an anisotropic virtual interconnect. No connectivity is achieved in these regions, between the first semiconductive device 116 and the subsequent semiconductive device 120. No electrical connection between the first semiconductive device 216 and the subsequent semiconductive device 220 is made, because the dispersion of electrically conductive particles 212 remains expanded and isolated in the matrix of the anisotropically conductive flexible film 210. Accordingly, a given compressive variation of the anisotropically conductive flexible film 210 is useful.

As illustrated in FIG. 2A, the anisotropically conductive flexible film 210 has a rest thickness 214, and as illustrated in FIG. 2B, the anisotropically conductive flexible film 210 has a compressed thickness 215 that is less than the rest thickness 214.

Hereinafter, embodiments with anisotropically conductive flexible films, may use embodiments depicted in either of FIGS. 1B and 2B, but reference is made to an anisotropically conductive flexible film, that may also be virtually, anisotropically conductive.

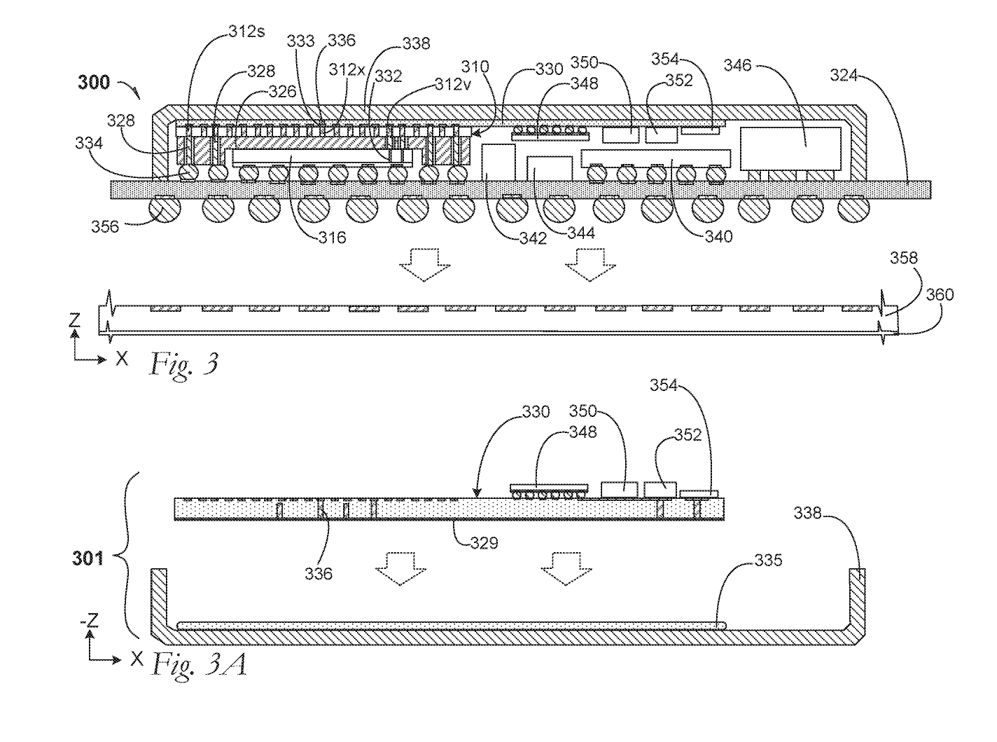

FIG. 3 is a cross-section elevation of a semiconductor device package 300 that includes an anisotropically conductive flexible film 310 with anisotropic electrical and heat conductivities according to an embodiment. The anisotropically conductive flexible film 310 exhibits anisotropic electrical conductivity with a plurality of electrically conductive channels 312. The anisotropically conductive flexible film 310 also exhibits anisotropic heat conductivity with a plurality of the electrically conductive channels 312 that abut at least one heat sink.

In an embodiment, a first semiconductive device 316 that may be referred to as a bottom device 316 is mounted on a first semiconductor package substrate 324. As illustrated, the first semiconductive device 316 is flip-chip mounted on the semiconductor package substrate 324. A heat sink 326 abuts the flip-chip mounted first semiconductive device 316.

In an embodiment, the heat sink 326 has the form factor of an integrated heat spreader (IHS) 326, which may also be referred to as a “lid” 326. In an embodiment, insulated through-sink vias 328 in the heat sink 326 connect the semiconductor package substrate 324 to the anisotropically conductive flexible film 310. A subsequent semiconductor package substrate 330 completes a connection from the first semiconductor package substrate 324, through the insulated through-sink via 328 and the anisotropically conductive flexible film 310. An electrical bump 334 on the first semiconductor package substrate 324 contacts the insulated through-sink via 328, which contacts an electrically conductive channel 312s within the anisotropically conductive flexible film 310. The electrically conductive channel 312s in turn contacts the subsequent semiconductor package substrate 330.

In an embodiment, electrical communication between the first semiconductor package substrate 324 and the subsequent semiconductor package substrate 330 allows for devices respectively disposed on the package substrates 324 and 330, to be physically closer to each other than if they were to be disposed on a single semiconductor package substrate, or on a board such as a motherboard. Consequently, an X-Y footprint of the semiconductor device package 300 is small, which allows for a smaller form factor with the same or higher computational function with equivalent components.

Although the several electrically conductive channels are depicted with the reference number base 312, the position of the channels within the semiconductor device package 300, create different structural context. In an embodiment, the electrically conductive channel 312s, completes a connection from the first semiconductor package substrate 324, through the insulated through-sink via 326 and the anisotropically conductive flexible film 310. This represents a substantially vertical composite interconnect that includes an electrical bump 334 on the first semiconductor package substrate 324, an insulated through-sink via 328, and the electrically conductive channel 312s. This substantially vertical composite interconnect 334, 328 and 312s is a substrate-to-substrate-bridging composite interconnect.

In an embodiment, an electrically conductive channel 312v completes a connection between the first semiconductive device 316, a through-silicon via 332 in the first semiconductive device 316, and to the subsequent semiconductor package substrate 330. This electrically conductive channel 312v with the anisotropically conductive flexible film 310 represents a die-to-substrate bridging composite interconnect.

In an embodiment, a heat-transfer conductive channel 312x in the anisotropically conductive flexible film 310 creates a composite heat-transfer structure. This composite heat-transfer structure allows heat flow from the first semiconductive device 316, the heat sink 326, the heat-transfer conductive channel 312x, and an optionally present bond pad 333 and a through-substrate via 336 to a shielding can 338 that encloses the several components of the semiconductor device package 300.

In an embodiment, bottom-side additional components include a second semiconductive device 340 on the first semiconductor package substrate 324. In an embodiment, the second semiconductive device 340 is a memory die. In an embodiment, other components 342, 344 and 346 are disposed on the first semiconductor package substrate 324.

In an embodiment, top-side additional components include a subsequent semiconductive device 348, and components 350, 352 and 354. In an embodiment, the subsequent semiconductive device 348 is a transceiver for wireless telecommunications. Communication between bottom devices 316, 340, 342, and 344 to top devices 348, 350, 352 and 354 are all bridged through the anisotropically conductive flexible film 310.

In an embodiment, the first semiconductor package substrate 324 is mounted through a board-side bump 356 to a board 358 such as a motherboard 358. After forming the electrical bumps 356 (one instance enumerated), the first semiconductor device substrate 324 is seated on the board 358, and in an embodiment, the board 358 includes an external shell 360 that provides both physical and electrical insulation for devices within the external shell 360.

FIG. 3A is a cross-section elevation of a portion of the semiconductor device package 300 depicted in FIG. 3 during assembly according to an embodiment. The semiconductor device package 301 is inverted along the X-axis such that a negative-Z direction is represented compared to the illustration in FIG. 3. Further, the subsequent semiconductor package substrate 330 is expanded along the Z-direction for more detail.

During assembly, an electrically conductive adhesive 335 is deposited into the shielding can 338, and the subsequent semiconductor package substrate 330 is seated onto the electrically conductive adhesive 335. In an embodiment, the adhesive 335 has dielectric but thermal conductivity properties.

Within the subsequent semiconductor package substrate 330 includes copper routing layers that connect the anisotropically conductive flexible film 310 (see FIG. 3) both with passive devices such as devices 350, 352, and 354 and a ground plane 329 within the subsequent semiconductor package substrate 330. Included within the subsequent semiconductor package substrate 330 are thermal vias such as the through-substrate via 336.

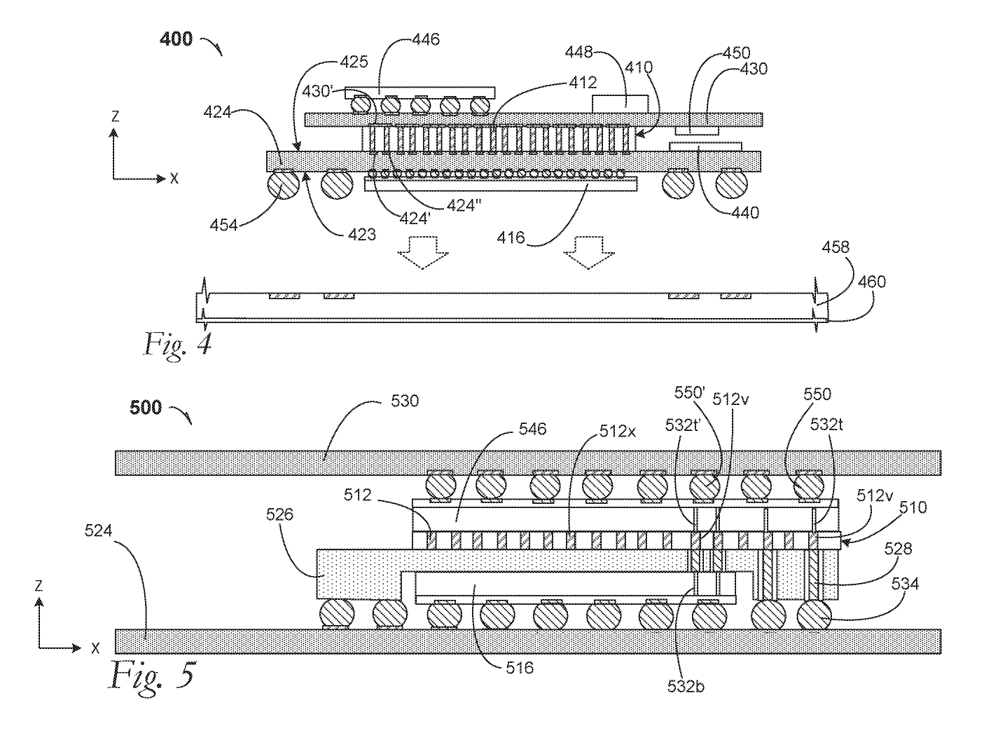

FIG. 4 is a cross-section elevation of a semiconductor device package 400 that includes an anisotropically conductive flexible film 410 with anisotropic electrical and heat conductivities according to an embodiment. The anisotropically conductive flexible film 410 exhibits anisotropic electrical conductivity with a plurality of electrically conductive channels 412.

In an embodiment, a first semiconductive device 416 that may be referred to as a bottom device 416 is mounted on a first semiconductor package substrate 424. As illustrated, the first semiconductive device 416 is flip-chip disposed opposite the anisotropically conductive flexible film 410. As illustrated, the first semiconductive device 416 is “opossum” mounted on the first semiconductor package substrate 424. In an embodiment, the first semiconductive device 416 is mounted on a land side 423, and opposite the land side 423 is a bridge side 425 onto which the anisotropically conductive flexible film 410 is mounted. In an embodiment, the anisotropically conductive flexible film 410 may be referred to as a bridge film 410.

In an embodiment, a subsequent semiconductor package substrate 430 completes a connection from the first semiconductor package substrate 424, through the bridge film 410. A subsequent semiconductive device 446 is disposed on the subsequent semiconductor package substrate 430. It can be seen a bilateral qualitative symmetry is depicted with the first and subsequent semiconductive devices 416 and 446 are connected across respective first and subsequent semiconductor package substrates 424 and 430, with the anisotropically conductive flexible film 410 disposed in the center. The qualitative symmetry means five structures are configured with the anisotropically conductive flexible film the central structure.

In an embodiment, electrical communication through the anisotropically conductive flexible film 410, between the first semiconductor package substrate 424 and the subsequent semiconductor package substrate 430, allows for devices respectively disposed on the package substrates 424 and 430, to be physically closer to each other than if they were to be disposed on a single semiconductor package substrate, or on a board such as a motherboard. Consequently, an X-Y footprint of the semiconductor device package 400 is small, which allows for a smaller form factor with the same or higher computational function with equivalent components. The several interconnects 412, represents a vertical interconnect that is a substrate-to-substrate-bridging interconnect.

In an embodiment, a bottom-side additional component 440 is disposed on the bridge side 425 of the first semiconductor package substrate 424.

In an embodiment, top-side additional components include the subsequent semiconductive device 446, and components 448 and 450. In an embodiment, the subsequent semiconductive device 446 is a memory die.

In an embodiment, the first semiconductor package substrate 424 is depicted being mounted through a hoard-side bump 454 to a board 458 such as a motherboard 458. After forming the electrical bumps 454 (one instance enumerated), the first semiconductor device substrate 424 is seated on the board 458, and in an embodiment, the board 458 includes an external shell 460 that provides both physical and electrical insulation for devices within the external shell 460.

Where connection pad sizes are different as these pads contact the anisotropically conductive flexible film 410, pitch matching is no necessary where the X-direction density of the several interconnects 412 may contact several bond pads, e.g., 424′ and 424″ on the first semiconductive package substrate 424, but e.g., only one 430′ (or a comparatively different bond-pad count) of the several contacts may contact a bond pad on the subsequent semiconductive package substrate 430.

FIG. 5 is a cross-section elevation of a semiconductor device package 500 that includes an anisotropically conductive flexible film 510 with anisotropic electrical and heat conductivities according to an embodiment. The anisotropically conductive flexible film 510 exhibits anisotropic electrical conductivity with a plurality of electrically conductive channels 512. The anisotropically conductive flexible film 510 also exhibits anisotropic heat conductivity with a plurality of the electrically conductive channels 512 that abut at least one heat sink.

In an embodiment, a first semiconductive device 516 that may be referred to as a bottom device 516 is mounted on a first semiconductor package substrate 524, and a subsequent semiconductive device 546 is disposed above a heat sink 526. The anisotropically conductive flexible film 510 is disposed between the heat sink 526 and the subsequent semiconductive device 546.

As illustrated, the first semiconductive device 516 is flip-chip mounted on the first semiconductor package substrate 524. The heat sink 526 abuts the flip-chip mounted first semiconductive device 516.

In an embodiment, the heat sink 526 has the form factor of an integrated heat spreader (IHS) 526, which may also be referred to as a “lid” 526. In an embodiment, insulated through-sink vias 528 in the heat sink 526 connect the first semiconductor package substrate 524 to the anisotropically conductive flexible film 510. The subsequent semiconductive device 546 is also flip-chip mounted onto a subsequent semiconductor package substrate 530.

One electrical communication path between the first semiconductor package substrate 524 and the subsequent semiconductor package substrate 530, includes an electrical bump 534 that contacts an insulated through-sink via 528. The insulated through-sink via 528 contacts an electrically conductive channel 512v in the anisotropically conductive flexible film 510. The electrically conductive channel 512v contacts a top-device through-silicon via 532t in the top or subsequent semiconductive device 546. And the subsequent semiconductive device 546 completes the connection from the first semiconductor package substrate 524 to the subsequent semiconductor package substrate 530 through a top electrical hump 550.

In an embodiment, one electrical communication path between the first semiconductor package substrate 524 and the subsequent semiconductor package substrate 530, includes two through-silicon via (TSV) structures, including a bottom TSV 532b and a top TSV 532t′, both of which contact an electrically conductive channel 512v in the anisotropically conductive flexible film 510. The electrically conductive channel 512v contacts both through-silicon via 532b in the bottom or first semiconductor device 516, and through-silicon via 532t′ in the top or subsequent semiconductive device 546. And the subsequent semiconductive device 546 completes the connection from the first semiconductor package substrate 524 to the subsequent semiconductor package substrate 530 through a top electrical bump 550′.

In an embodiment, electrical communication between the first semiconductor package substrate 524 and the subsequent semiconductor package substrate 530, allows for devices respectively disposed on the package substrates 524 and 530, to be physically closer to each other than if they were to be disposed on a single semiconductor package substrate, or on a board such as a motherboard. Consequently, an X-Y footprint of the semiconductor device package 300 is small, which allows for a smaller form factor with the same or higher computational function with equivalent components.

In an embodiment, a heat-transfer conductive channel 512x in the isotropically conductive flexible film 510 is part of a composite heat-transfer structure. This composite heat-transfer structure allows heat flow from the first semiconductive device 516, the heat sink 526, the heat-transfer conductive channel 512x, and the subsequent semiconductive device 546.

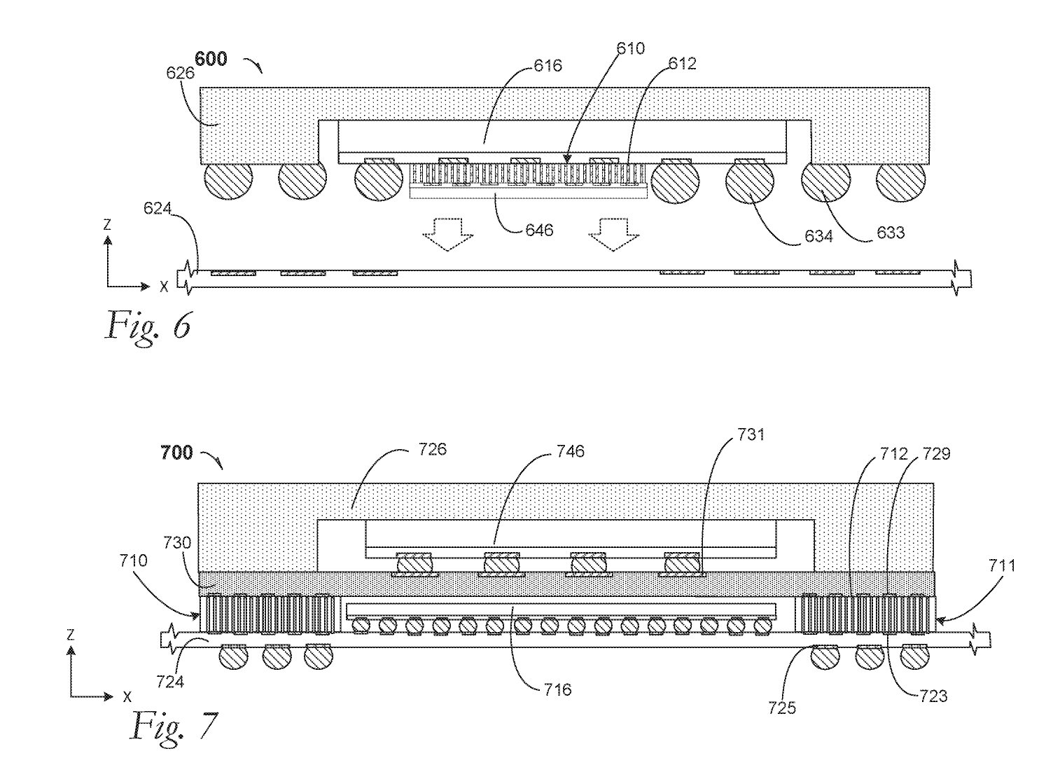

FIG. 6 is a cross-section elevation of a semiconductor device package 600 that includes an anisotropically conductive flexible film 610 with anisotropic electrical and heat conductivities according to an embodiment. The anisotropically conductive flexible film 610 exhibits anisotropic electrical conductivity with a plurality of electrically conductive channels 612.

In an embodiment, a first semiconductive device 616 is seated at a backside into a heat sink 626. A subsequent semiconductive device 646 is disposed face-to-face with the first semiconductive device 616 with the anisotropically conductive flexible film 610 disposed between the first semiconductive device 616 and the subsequent semiconductive device 646.

As illustrated, the first semiconductive device 616 is to be flip-chip mounted onto a semiconductor package substrate 624, and the subsequent semiconductive device 646 “opossum” hangs below the first semiconductive device with the anisotropically conductive flexible film 610 as the electronic interface between the two devices 616 and 646.

In an embodiment, the heat sink 626 has the form factor of an integrated heat spreader (IHS) 626, which may also be referred to as a “lid” 626, but it includes sufficient contact area to bond with the semiconductor package substrate 624 with dummy bumps 633, while selected electrical bumps 634 created electronic connection to the semiconductor package substrate 624.

In an embodiment, pitch matching between the two semiconductive devices 616 and 646 is resolved by the several occurrences of the electrically conductive channels 612, similarly to that illustrated and described for the semiconductive device package 400 depicted in FIG. 4.

FIG. 7 is a cross-section elevation of a semiconductor device package-on-package 700 that includes anisotropically conductive flexible films 710 and 711 with anisotropic electrical and heat conductivities according to an embodiment. The anisotropically conductive flexible films 710 and 711 exhibit anisotropic electrical conductivity with a plurality of electrically conductive channels 712. In an embodiment, a first semiconductive device 716 that may be referred to as a bottom device 716 is mounted on a first semiconductor package substrate 724. As illustrated, the first semiconductive device 716 is flip-chip mounted on the first semiconductor package substrate 724. In an embodiment, the anisotropically conductive flexible films 710 and 711 may be referred to as bridge films 710 and 711.

In an embodiment, a subsequent semiconductor package substrate 730 completes a connection from the first semiconductor package substrate 724, through the bridging anisotropically conductive flexible films 710 and 711, which act as a package-on-package (POP) interconnects 710 and 711. A subsequent semiconductive device 746 is disposed on the subsequent semiconductor package substrate 730 as part of a POP device 746. In an embodiment, a heat sink 726 abuts the subsequent semiconductive device 746, and a bond pad 731 contacts both the subsequent semiconductive device 746 and the subsequent semiconductor package substrate 730.

In an embodiment, electrical communication through the anisotropically conductive flexible films 710 and 711, between the first semiconductor package substrate 724 and the subsequent semiconductor package substrate 730 includes several occurrences of the electrically conductive channels 712 that are coupled with bond pads 725 on first semiconductor package substrate 724 land side, and bond pads 723 on a first semiconductor package substrate 724 die side. The semiconductor device package 700 allows for devices respectively disposed on the package substrates 724 and 730, to be physically closer to each other than if they were to be disposed on a single semiconductor package substrate, or on a board such as a motherboard. Consequently, an X-Y footprint of the semiconductor device package 700 is small, which allows for a smaller form factor with the same or higher computational function with equivalent components. The several interconnects 712, represents vertical interconnects that are a substrate-to-substrate-bridging interconnect.

In an embodiment, pitch matching between the two semiconductor package substrates 724 and 730 is resolved by the several occurrences of the electrically conductive channels 712, similarly to that illustrated and described for the semiconductive device package 400 depicted in FIG. 4.

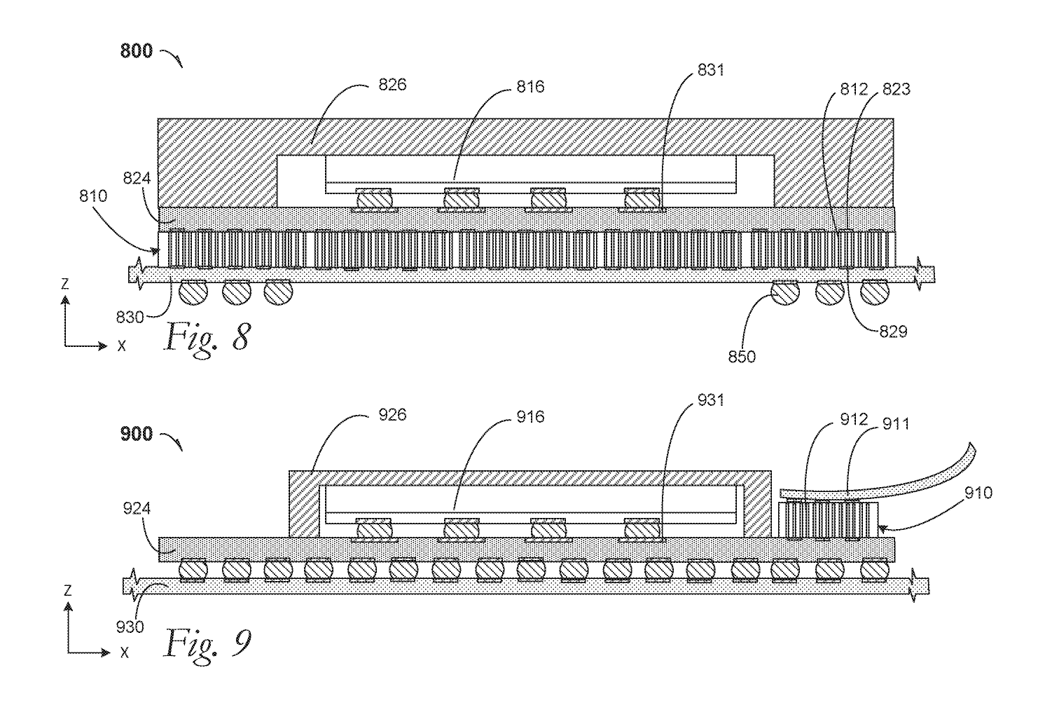

FIG. 8 is a cross-section elevation of a semiconductor device package 800 that includes an anisotropically conductive flexible film 810 with anisotropic electrical and heat conductivities according to an embodiment. The anisotropically conductive flexible film 810 exhibits anisotropic electrical conductivity with a plurality of electrically conductive channels 812.

In an embodiment, the first semiconductive device 816 abuts a heat sink 826, which in turn is seated on a first semiconductor package substrate 824 at a bond pad 831, and a bond pad 831 contacts both the first semiconductive device 816 and the first semiconductor package substrate 824. The anisotropically conductive flexible film 810 contacts both the first semiconductor package substrate 824 and a subsequent semiconductor package substrate 830.

In an embodiment and as illustrated, a series of first bond pads 823 contact at least one electrically conductive channel 812, and a series of subsequent bond pads 829 on a subsequent semiconductor substrate 830 also contact at least one electrically conductive channel 812. As illustrated and in an embodiment, where the enumerated respective first and subsequent bond pads 823 and 829 contact at least one conductive channel 812, the respective bond pads 823 and 829 contact the same three conductive channels 812. Although the pitch of the respective bond pads 823 and 829 are the same as illustrated, in an embodiment, the respective pitches are different for the bond pads similarly as illustrated for FIG. 4.

FIG. 9 is a cross-section elevation of a semiconductor device package 900 that includes an anisotropically conductive flexible film 910 that couples with a ribbon (or flex) interconnect 911 according to an embodiment. A first semiconductive device 916 abuts a heat sink 926 at a bond pad 931, and the bond pad 931 contacts both the first semiconductive device 916 and a first semiconductor package substrate 924.

The anisotropically conductive flexible film 910 exhibits anisotropic electrical conductivity with a plurality of electrically conductive channels 912. Because of the plurality of electrically conductive channels 912 include a sub-plurality of these channels 912 contacting each bond pad, an electrical connection to the ribbon interconnect 911 is achieved.

In an embodiment, a first semiconductive device 916 is mounted on the first semiconductor package substrate 924. As illustrated, the first semiconductive device 916 is flip-chip mounted on the first semiconductor package substrate 924, and electrical communication to the anisotropically conductive flexible film 910 and to the ribbon interconnect 911 is accomplished through the first semiconductor package substrate 924.

In an embodiment, a subsequent semiconductor package substrate 930 completes a connection from the first semiconductor package substrate 924. In an embodiment, the subsequent semiconductor package substrate 930 is a board such as a motherboard.

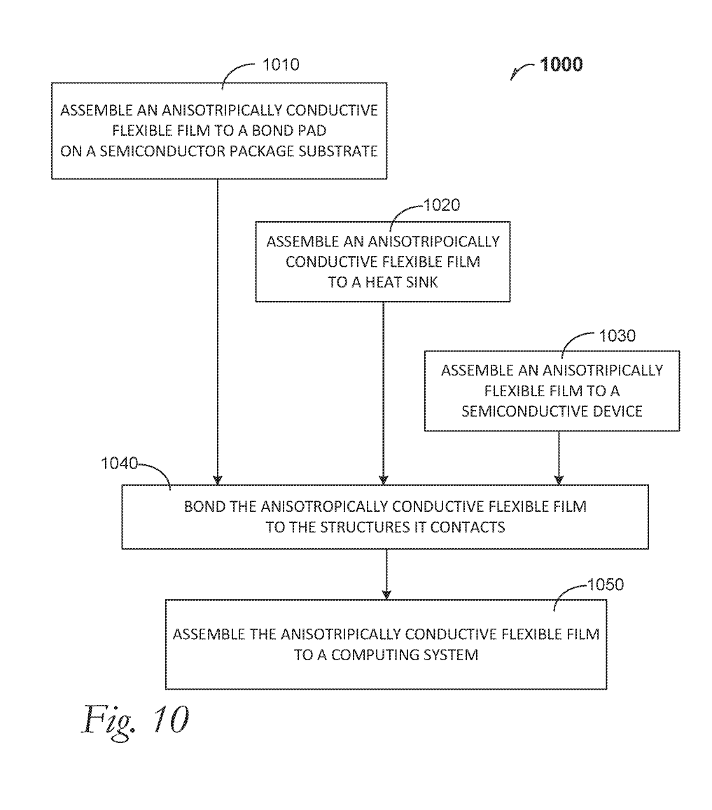

FIG. 10 is a process flow diagram 1000 for assembling a semiconductor device package according to several embodiments.

At 1010, the process includes assembling an anisotropically conductive flexible film to a bond pad of semiconductor device substrate.

At 1020, the process includes assembling an anisotropically conductive flexible film to a heat sink.

At 1030, the process includes assembling an anisotropically conductive flexible film to a bond pad of a semiconductive device.

In an embodiment, the processes of items 1010 and 1020 are depicted in FIG. 3 where the anisotropically conductive flexible film 310 contacts the subsequent semiconductor package substrate 330 and the heat sink 326.

In an embodiment, the processes of item 1020 and 1030 are depicted in FIG. 5 where the anisotropically conductive flexible film 510 contacts the heat sink 526 and the subsequent semiconductive device 546.

At 1040, the process includes bonding the anisotropically conductive flexible film to the structures it contacts. In a non-limiting example embodiment, a thermal-compression bonding technique is used to bond the anisotropically conductive flexible film to any two or more of the three surface types. In an embodiment, compressing the anisotropically conductive flexible film is carried out where the virtual anisotropic interconnects 213 depicted in FIG. 2B are formed.

At 1050, the process includes assembling the anisotropically conductive flexible film to a computing system.

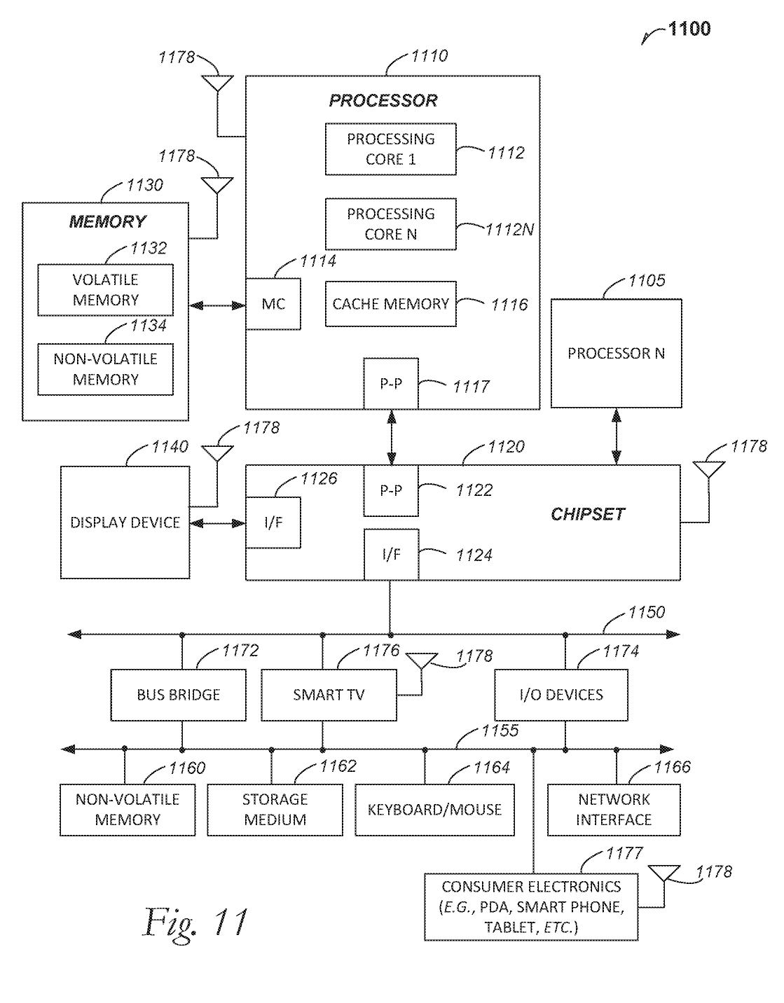

FIG. 11 is included to show an example of a higher-level device application for the disclosed embodiments. The anisotropically conductive flexible film embodiments may be found in several parts of a computing system. In an embodiment, the anisotropically conductive flexible film is part of a communications apparatus such as is affixed to a cellular communications tower. The anisotropically conductive flexible film embodiments may also be referred to as a system-in-package with a wide-band phased-array antenna apparatus. In an embodiment, a computing system 1100 includes, but is not limited to, a desktop computer. In an embodiment, a system 1100 includes, but is not limited to a laptop computer. In an embodiment, a system 1100 includes, but is not limited to a netbook. In an embodiment, a system 600 includes, but is not limited to a tablet. In an embodiment, a system 1100 includes, but is not limited to a notebook computer. In an embodiment, a system 1100 includes, but is not limited to a personal digital assistant (PDA). In an embodiment, a system 1100 includes, but is not limited to a server. In an embodiment, a system 1100 includes, but is not limited to a workstation. In an embodiment, a system 1100 includes, but is not limited to a cellular telephone. In an embodiment, a system 1100 includes, but is not limited to a mobile computing device. In an embodiment, a system 1100 includes, but is not limited to a smart phone. In an embodiment, a system 1100 includes, but is not limited to an internet appliance. Other types of computing devices may be configured with the microelectronic device that includes anisotropically conductive flexible film embodiments.

In air embodiment, the processor 1110 has one or more processing cores 1112 and 1112N, where 1112N represents the Nth processor core inside processor 1110 where N is a positive integer. In an embodiment, the electronic device system 1100 using anisotropically conductive flexible film embodiments that includes multiple processors including 1110 and 1105, where the processor 1105 has logic similar or identical to the logic of the processor 1110. In an embodiment, the processing core 1112 includes, but is not limited to, pre-fetch logic to fetch instructions, decode logic to decode the instructions, execution logic to execute instructions and the like. In an embodiment, the processor 1110 has a cache memory 1116 to cache at least one of instructions and data for the isotropically conductive flexible film embodiments in the system 1100. The cache memory 1116 may be organized into a hierarchal structure including one or more levels of cache memory.

In an embodiment, the processor 1110 includes a memory controller 1114, which is operable to perform functions that enable the processor 1110 to access and communicate with memory 1130 that includes at least one of a volatile memory 1132 and a non-volatile memory 1134. In an embodiment, the processor 1110 is coupled with memory 1130 and chipset 1120. In an embodiment, the chipset 1120 is part of anisotropically conductive flexible film embodiments depicted in FIGS. 1A, 1B, 2A, 2B, and 3 through 9. The processor 1110 may also be coupled to a wireless antenna 1178 to communicate with any device configured to at least one of transmit and receive wireless signals. In an embodiment, the wireless antenna interface 1178 operates in accordance with, but is not limited to, the IEEE 802.11 standard and its related family, Home Plug AV (HPAV), Ultra Wide Band (UWB), Bluetooth, WiMax, or any form of wireless communication protocol.

In an embodiment, the volatile memory 1132 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. The non-volatile memory 1134 includes, but is not limited to, flash memory, phase change memory (PCM), read-only memory (ROM), electrically erasable programmable read-only memory (EEPROM), or any other type of non-volatile memory device.

The memory 1130 stores information and instructions to be executed by the processor 1110. In an embodiment, the memory 1130 may also store temporary variables or other intermediate information while the processor 1110 is executing instructions. In the illustrated embodiment, the chipset 1120 connects with processor 1110 via Point-to-Point (PtP or P-P) interfaces 1117 and 1122. Either of these PtP embodiments may be achieved using anisotropically conductive flexible film embodiments as set forth in this disclosure. The chipset 1120 enables the processor 1110 to connect to other elements in anisotropically conductive flexible film embodiments in a system 1100. In an embodiment, interfaces 1117 and 1122 operate in accordance with a PtP communication protocol such as the Intel® QuickPath Interconnect (QPI) or the like. In other embodiments, a different interconnect may be used.

In an embodiment, the chipset 1120 is operable to communicate with the processor 1110, 1105N, the display device 1140, and other devices 1172, 1176, 1174, 1160, 1162, 1164, 1166, 1177, etc. The chipset 1120 may also be coupled to a wireless antenna 1178 to communicate with any device configured to at least do one of transmit and receive wireless signals.

The chipset 1120 connects to the display device 1140 via the interface 1126. The display 1140 may be, for example, a liquid crystal display (LCD), a plasma display, cathode ray tube (CRT) display, or any other form of visual display device. In an embodiment, the processor 1110 and the chipset 1120 are merged into a system-in-package with a wide-band phased-array antenna module apparatus in a system. Additionally, the chipset 1120 connects to one or more buses 1150 and 1155 that interconnect various elements 1174, 1160, 1162, 1164, and 1166. Buses 1150 and 1155 may be interconnected together via a bus bridge 1172 such as at least one isotropically conductive flexible film embodiment. In an embodiment, the chipset 1120, via interface 1124, couples with a non-volatile memory 1160, a mass storage device(s) 1162, a keyboard/mouse 1164, a network interface 1166, smart TV 1176, and the consumer electronics 1177, etc.

In an embodiment, the mass storage device 1162 includes, but is not limited to, a solid state drive, a hard disk drive, a universal serial bus flash memory drive, or any other form of computer data storage medium. In one embodiment, the network interface 1166 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra Wide Band (UWB), Bluetooth, WiMax, or any form of wireless communication protocol.

While the modules shown in FIG. 11 are depicted as separate blocks within the isotropically conductive flexible film embodiments in a computing system 1100, the functions performed by some of these blocks may he integrated within a single semiconductor circuit or may be implemented using two or more separate integrated circuits. For example, although cache memory 1116 is depicted as a separate block within processor 1110, cache memory 1116 (or selected aspects of 1116) can be incorporated into the processor core 1112.

Where useful, the computing system 1100 may have a broadcasting structure interface such as for affixing the apparatus to a cellular tower.

To illustrate the anisotropically conductive flexible film embodiments and methods disclosed herein, a non-limiting list of examples is provided herein:

Example 1 is a semiconductor device package, comprising: an anisotropically conductive flexible film including a plurality of electrically conductive corridors disposed therein; a semiconductor package substrate coupled to the anisotropically conductive flexible film; and a semiconductive device, wherein at least one of the semiconductor package substrate and the semiconductive device is in direct contact with the anisotropically conductive flexible film.

In Example 2, the subject matter of Example 1 optionally includes wherein the anisotropically conductive flexible film includes virtual anisotropic interconnects.

In Example 3, the subject matter of any one or more of Examples 1-2 optionally include wherein the semiconductor package substrate is a subsequent semiconductor package substrate, further including: a first semiconductor package substrate, wherein the semiconductive device is flip-chip disposed on the first semiconductor package substrate; a heat sink in direct contact with the anisotropically conductive flexible film, wherein the heat sink includes an insulated through-sink via, wherein the insulated through-sink via contacts both the first semiconductor package substrate and the anisotropically conductive flexible film; wherein the anisotropically conductive flexible film is in direct contact with the subsequent semiconductor package substrate; and a subsequent device disposed on the subsequent semiconductor package substrate.

In Example 4, the subject matter of any one or more of Examples 1-3 optionally include wherein the semiconductor package substrate is a subsequent semiconductor package substrate, further including: a first semiconductor package substrate, wherein the semiconductive device is flip-chip disposed on the first semiconductor package substrate; a heat sink in direct contact with the anisotropically conductive flexible film, wherein the heat sink includes an insulated through-sink via, wherein the insulated through-sink via contacts both the first semiconductor package substrate and the anisotropically conductive flexible film; wherein the anisotropically conductive flexible film is in direct contact with the subsequent semiconductor package substrate; a subsequent device disposed on the subsequent semiconductor package substrate; a third semiconductive device disposed on the first semiconductor package substrate; at least two passive devices, one each of which is disposed on one of the first semiconductor package substrate and the subsequent semiconductor package substrate.

In Example 5, the subject matter of any one or more of Examples 1-4 optionally include wherein the semiconductor package substrate is a subsequent semiconductor package substrate, further including: a first semiconductor package substrate, wherein the semiconductive device is flip-chip disposed on the first semiconductor package substrate; a heat sink in direct contact with the anisotropically conductive flexible film, wherein the heat sink includes an insulated through-sink via, wherein the insulated through-sink via contacts both the first semiconductor package substrate and the anisotropically conductive flexible film; wherein the anisotropically conductive flexible film is in direct contact with the subsequent semiconductor package substrate; a subsequent semiconductive device disposed on the subsequent semiconductor package substrate; wherein the anisotropically conductive flexible film is also in direct contact with the heat sink; and a shielding can disposed on the first semiconductor package substrate, wherein the shielding can encloses the first and subsequent semiconductive devices.

In Example 6, the subject matter of any one or more of Examples 1-5 optionally include wherein the semiconductor package substrate is a first semiconductor package substrate, further including: a subsequent semiconductor package substrate, wherein the first semiconductor package substrate and the subsequent semiconductor package substrate each abuts the anisotropically conductive flexible film, and wherein the semiconductive device is disposed the first semiconductor package substrate opposite the anisotropically conductive flexible film.

In Example 7, the subject matter of any one or more of Examples 1-6 optionally include wherein the semiconductor package substrate is a first semiconductor package substrate, and wherein the semiconductive device is a first semiconductive device, further including: a subsequent semiconductor package substrate, wherein the first semiconductor package substrate and the subsequent semiconductor package substrate each abuts the anisotropically conductive flexible film, and wherein the first semiconductive device is disposed on the first semiconductor package substrate opposite the anisotropically conductive flexible film; a subsequent semiconductive device disposed on the subsequent semiconductor package substrate, wherein a bilateral qualitative symmetry is configured with the first semiconductive device, the first semiconductor package substrate, the anisotropically conductive flexible film, the subsequent semiconductor package substrate, and the subsequent semiconductive device.

In Example 8, the subject matter of any one or more of Examples 1-7 optionally include wherein the semiconductor package substrate is a subsequent semiconductor package substrate, and the semiconductive device is a subsequent semiconductive device disposed on the subsequent semiconductor package substrate, further including: a first semiconductive device disposed on a first semiconductor package substrate; a heat sink that abuts the first semiconductive device and that is in direct contact with the anisotropically conductive flexible film, wherein the heat sink includes an insulated through-sink via, wherein the insulated through-sink via contacts the anisotropically conductive flexible film and the first semiconductor package substrate, and the anisotropically conductive flexible film contacts the subsequent semiconductive device; and wherein the subsequent semiconductive device abuts the anisotropically conductive flexible film.

In Example 9, the subject matter of any one or more of Examples 1-8 optionally include wherein the semiconductive device is a first semiconductive device, further including: a subsequent semiconductive device; a heat sink that abuts the subsequent semiconductive device, wherein the first and subsequent semiconductive devices are seated on the anisotropically conductive flexible film; and wherein the semiconductor package substrate is bonded to each of the heat sink and the subsequent semiconductive device.

In Example 10, the subject matter of any one or more of Examples 1-9 optionally include wherein the semiconductive device is a first semiconductive device, further including: a subsequent semiconductive device; a heat sink that abuts the subsequent semiconductive device, wherein the first and subsequent semiconductive devices are seated on the anisotropically conductive flexible film; and wherein the semiconductor package substrate is bonded to each of the heat sink and the subsequent semiconductive device, and wherein the first semiconductive device is suspended from the anisotropically conductive flexible film, above the semiconductor device package.

In Example 11, the subject matter of any one or more of Examples 1-10 optionally include wherein the anisotropically conductive flexible film is a first anisotropically conductive flexible film, further including: a subsequent anisotropically conductive flexible film, that forms with the first anisotropically conductive flexible film, a package-on-package interconnect structure; a subsequent semiconductor package, wherein the first and subsequent anisotropically conductive flexible films support the subsequent semiconductor package above the first semiconductor package; and a subsequent semiconductive device disposed on the subsequent semiconductor package.

In Example 12, the subject matter of any one or more of Examples 1-11 optionally include wherein the anisotropically conductive flexible film is a first anisotropically conductive flexible film, further including: a subsequent anisotropically conductive flexible film, that forms a package-on-package interconnect structure with the first anisotropically conductive flexible film; a subsequent semiconductor package, wherein the first and subsequent anisotropically conductive flexible films support the subsequent semiconductor package above the first semiconductor package; a subsequent semiconductive device disposed on the subsequent semiconductor package; and a heat sink disposed on the subsequent semiconductor package, wherein the heat sink abuts the subsequent semiconductive device.

In Example 13, the subject matter of any one or mare of Examples 1-12 optionally include wherein the semiconductor package substrate is a first semiconductor package substrate that abuts the anisotropically conductive flexible film, further including: a subsequent semiconductor package substrate that abuts the anisotropically conductive flexible film, wherein the semiconductive device is disposed on the subsequent semiconductor device substrate; and wherein the anisotropically conductive flexible film includes more than one anisotropic contact corridor that contact a single bond pad on at least one of the first and subsequent semiconductor package substrates.

In Example 14, the subject matter of any one or more of Examples 1-13 optionally include wherein the semiconductor package substrate is a first semiconductor package substrate that abuts the anisotropically conductive flexible film, further including: a subsequent semiconductor package substrate that abuts the anisotropically conductive flexible film, wherein the semiconductive device is disposed on the subsequent semiconductor device substrate; wherein the anisotropically conductive flexible film includes more than one anisotropic contact corridor that contact a single bond pad on at least one of the first and subsequent semiconductor package substrates; and a heat sink seated on the subsequent semiconductor package substrate, wherein the heat sink also abuts the semiconductive device.

In Example 15, the subject matter of any one or more of Examples 1-14 optionally include wherein the semiconductor package substrate is a first semiconductor package substrate, further including: a subsequent semiconductor package substrate disposed below the first semiconductor package substrate; a ribbon connector that contacts the anisotropically conductive flexible film, wherein the anisotropically conductive flexible film contacts the first semiconductor package substrate, and wherein the semiconductive device is disposed on the first semiconductor package substrate; and a heat sink seated on the first semiconductor package substrate, wherein the heat sink also abuts the semiconductive device.

Example 16 is a process of assembling a semiconductor device package, comprising: assembling an anisotropically conductive flexible film to at least one of: a bond pad on a semiconductor package substrate; a bond pad on a semiconductive device; and a heat sink; bonding the anisotropically conductive flexible film under conditions to form at least one of an electronic connection and a heat-transfer conductive channel.

In Example 17, the subject matter of Example 16 optionally includes wherein the semiconductor package substrate is a subsequent semiconductor package substrate, further including: assembling a first semiconductor package substrate to the heat sink; and assembling a shielding can to the semiconductor package substrate.

In Example 18, the subject matter of any one or more of Examples 16-17 optionally include wherein the semiconductor package substrate is a first semiconductor package substrate, further including: assembling a subsequent semiconductor package substrate to the anisotropically conductive flexible film, and wherein the semiconductive device is disposed on the first semiconductor package substrate opposite the anisotropically conductive flexible film; and assembling a subsequent semiconductive device on the subsequent semiconductor package substrate, wherein a bilateral qualitative symmetry is configured with the first semiconductive device, the first semiconductor package substrate, the anisotropically conductive flexible film, the subsequent semiconductor package substrate, and the subsequent semiconductive device.

In Example 19, the subject matter of any one or more of Examples 16-18 optionally include wherein the semiconductor package substrate is a subsequent semiconductor package substrate, and the semiconductive device is a subsequent semiconductive device disposed on the subsequent semiconductor package substrate, further including: assembling a first semiconductive device on a first semiconductor package substrate; wherein assembling the heat sink to abut the first semiconductive device and that is in direct contact with the anisotropically, conductive flexible film, wherein the heat sink includes an insulated through-sink via, wherein the insulated through-sink via contacts the anisotropically, conductive flexible film and the first semiconductor package substrate, and the anisotropically conductive flexible film contacts the subsequent semiconductive device; and wherein assembling the subsequent semiconductive device to abut the anisotropically conductive flexible film.

In Example 20, the subject matter of any one or more of Examples 16-19 optionally include wherein the semiconductive device is a first semiconductive device, further including: assembling a subsequent semiconductive device to the first semiconductive device through the anisotropically conductive flexible film; and wherein assembling the heat sink to abut the subsequent semiconductive device; and wherein bonding the anisotropically conductive flexible film causes the semiconductor package substrate to be bonded to each of the heat sink and the subsequent semiconductive device.

In Example 21, the subject matter of any one or more of Examples 16-20 optionally include wherein the anisotropically conductive flexible film is a first anisotropically conductive flexible film, further including: bonding a subsequent anisotropically conductive flexible film to form a package-on-package interconnect structure with the with the first anisotropically conductive flexible film; seating the semiconductive device on the subsequent semiconductor package, wherein the first and subsequent anisotropically conductive flexible films support the subsequent semiconductor package above the first semiconductor package; and seating a heat sink on the subsequent semiconductive device disposed on the subsequent semiconductor package.

In Example 22, the subject matter of any one or more of Examples 16-21 optionally include wherein the semiconductor package substrate is a first semiconductor package substrate that is assembled to the anisotropically conductive flexible film, further including: assembling a subsequent semiconductor package substrate to abut the anisotropically conductive flexible film, wherein the semiconductive device is disposed on the subsequent semiconductor device substrate; and wherein bonding includes bonding the anisotropically conductive flexible film to include more than one anisotropic contact corridor contacting a single bond pad on at least one of the first and subsequent semiconductor package substrates.

In Example 23, the subject matter of any one or mare of Examples 16-22 optionally include wherein the semiconductor package substrate is a first semiconductor package substrate, further including: bonding a subsequent semiconductor package substrate below the first semiconductor package substrate; bonding a ribbon connector to contact the anisotropically conductive flexible film, wherein the anisotropically conductive flexible film contacts the first semiconductor package substrate, and wherein the semiconductive device is disposed on the first semiconductor package substrate; and seating a heat sink on the first semiconductor package substrate, wherein the heat sink also abuts the semiconductive device.

Example 24 is a computing system, comprising: an anisotropically conductive flexible film including a plurality of electrically conductive corridors disposed therein; a semiconductor package substrate coupled to the anisotropically conductive flexible film; a semiconductive device, wherein at least one of the semiconductor package substrate and the semiconductive device is in direct contact with the anisotropically conductive flexible film; and wherein the semiconductive device is coupled with memory and a chipset.

In Example 25, the subject matter of Example 24 optionally includes a board to which the semiconductor package substrate is coupled; and a heat sink seated on the board, wherein the heat sink also contacts the anisotropically conductive flexible film.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Method examples described herein can be machine or computer-implemented at least in part. Some examples can include a computer-readable medium or machine-readable medium encoded with instructions operable to configure an electrical device to perform methods as described in the above examples. An implementation of such methods can include code, such as microcode, assembly language code, a higher-level language code, or the like. Such code can include computer readable instructions for performing various methods. The code may form portions of computer program products. Further, in an example, the code can be tangibly stored on one or more volatile, non-transitory, or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments can be combined with each other in various combinations or permutations. The scope of the disclosed embodiments should be determined with reference to the appended claims, along with the full scope of equivalents to which such claims are entitled.

1. A semiconductor device package, comprising:
an anisotropically conductive flexible film including a plurality of electrically conductive corridors disposed therein;
a semiconductor package substrate coupled to the anisotropically conductive flexible film; and
a semiconductive device, wherein at least one of the semiconductor package substrate and the semiconductive device is in direct contact with the anisotropically conductive flexible film.

2. The semiconductor device package of claim 1, wherein the anisotropically conductive flexible film includes virtual anisotropic interconnects.

3. The semiconductor device package of claim 1, wherein the semiconductor package substrate is a subsequent semiconductor package substrate, further including:
a first semiconductor package substrate, wherein the semiconductive device is flip-chip disposed on the first semiconductor package substrate;
a heat sink in direct contact with the anisotropically conductive flexible film, wherein the heat sink includes an insulated through-sink via, wherein the insulated through-sink via contacts both the first semiconductor package substrate and the anisotropically conductive flexible film;
wherein the anisotropically conductive flexible film is in direct contact with the subsequent semiconductor package substrate; and
a subsequent device disposed on the subsequent semiconductor package substrate.

4. The semiconductor device package of claim 1, wherein the semiconductor package substrate is a subsequent semiconductor package substrate, further including:
a first semiconductor package substrate, wherein the semiconductive device is flip-chip disposed on the first semiconductor package substrate;
a heat sink in direct contact with the anisotropically conductive flexible film, wherein the heat sink includes an insulated through-sink via, wherein the insulated through-sink via contacts both the first semiconductor package substrate and the anisotropically conductive flexible film;
wherein the anisotropically conductive flexible film is in direct contact with the subsequent semiconductor package substrate;
a subsequent device disposed on the subsequent semiconductor package substrate;
a third semiconductive device disposed on the first semiconductor package substrate;
at least two passive devices, one each of which is disposed on one of the first semiconductor package substrate and the subsequent semiconductor package substrate.

5. The semiconductor device package of claim 1, wherein the semiconductor package substrate is a subsequent semiconductor package substrate, further including:
a first semiconductor package substrate, wherein the semiconductive device is flip-chip disposed on the first semiconductor package substrate;
a heat sink in direct contact with the anisotropically conductive flexible film, wherein the heat sink includes an insulated through-sink via, wherein the insulated through-sink via contacts both the first semiconductor package substrate and the anisotropically conductive flexible film;
wherein the anisotropically conductive flexible film is in direct contact with the subsequent semiconductor package substrate;
a subsequent semiconductive device disposed on the subsequent semiconductor package substrate;
wherein the anisotropically conductive flexible film is also in direct contact with the heat sink; and
a shielding can disposed on the first semiconductor package substrate, wherein the shielding can encloses the first and subsequent semiconductive devices.

6. The semiconductive device package of claim 1, wherein the semiconductor package substrate is a first semiconductor package substrate, further including:
a subsequent semiconductor package substrate, wherein the first semiconductor package substrate and the subsequent semiconductor package substrate each abuts the anisotropically conductive flexible film, and wherein the semiconductive device is disposed the first semiconductor package substrate opposite the anisotropically conductive flexible film.

7. The semiconductive device package of claim 1, wherein the semiconductor package substrate is a first semiconductor package substrate, and wherein the semiconductive device is a first semiconductive device, further including:
a subsequent semiconductor package substrate, wherein the first semiconductor package substrate and the subsequent semiconductor package substrate each abuts the anisotropically conductive flexible film, and wherein the first semiconductive device is disposed on the first semiconductor package substrate opposite the anisotropically conductive flexible film;
a subsequent semiconductive device disposed on the subsequent semiconductor package substrate, wherein a bilateral qualitative symmetry is configured with the first semiconductive device, the first semiconductor package substrate, the anisotropically conductive flexible film, the subsequent semiconductor package substrate, and the subsequent semiconductive device.

8. The semiconductor device package of claim 1, wherein the semiconductor package substrate is a subsequent semiconductor package substrate, and the semiconductive device is a subsequent semiconductive device disposed on the subsequent semiconductor package substrate, further including:
a first semiconductive device disposed on a first semiconductor package substrate:
a heat sink that abuts the first semiconductive device and that is in direct contact with the anisotropically conductive flexible film, wherein the heat sink includes an insulated through-sink via, wherein the insulated through-sink via contacts the anisotropically conductive flexible film and the first semiconductor package substrate, and the anisotropically conductive flexible film contacts the subsequent semiconductive device; and
wherein the subsequent semiconductive device abuts the anisotropically conductive flexible film.

9. The semiconductor device package of claim 1, wherein the semiconductive device is a first semiconductive device, further including:
a subsequent semiconductive device;
a heat sink that abuts the subsequent semiconductive device, wherein the first and subsequent semiconductive devices are seated on the anisotropically conductive flexible film; and
wherein the semiconductor package substrate is bonded to each of the heat sink and the subsequent semiconductive device.

10. The semiconductor device package of claim 1, wherein the semiconductive device is a first semiconductive device, further including:
a subsequent semiconductive device;
a heat sink that abuts the subsequent semiconductive device, wherein the first and subsequent semiconductive devices are seated on the anisotropically conductive flexible film; and
wherein the semiconductor package substrate is bonded to each of the heat sink and the subsequent semiconductive device, and wherein the first semiconductive device is suspended from the anisotropically conductive flexible film, above the semiconductor device package.

11. The semiconductor device package of claim 1, wherein the anisotropically conductive flexible film is a first anisotropically conductive flexible film, further including:
a subsequent anisotropically conductive flexible film, that forms with the first anisotropically conductive flexible film, a package-on-package interconnect structure;
a subsequent semiconductor package, wherein the first and subsequent anisotropically conductive flexible films support the subsequent semiconductor package above the first semiconductor package; and
a subsequent semiconductive device disposed on the subsequent semiconductor package.

12. The semiconductor device package of claim 1, wherein the anisotropically conductive flexible film is a first anisotropically conductive flexible film, further including:
a subsequent anisotropically conductive flexible film, that forms a package-on-package interconnect structure with the first anisotropically conductive flexible film;
a subsequent semiconductor package, wherein the first and subsequent anisotropically conductive flexible films support the subsequent semiconductor package above the first semiconductor package;
a subsequent semiconductive device disposed on the subsequent semiconductor package; and
a heat sink disposed on the subsequent semiconductor package, wherein the heat sink abuts the subsequent semiconductive device.

13. The semiconductor device package of claim 1, wherein the semiconductor package substrate is a first semiconductor package substrate that abuts the anisotropically, conductive flexible film, further including:
a subsequent semiconductor package substrate that abuts the anisotropically conductive flexible film, wherein the semiconductive device is disposed on the subsequent semiconductor device substrate; and
wherein the anisotropically conductive flexible film includes more than one anisotropic contact corridor that contact a single bond pad on at least one of the first and subsequent semiconductor package substrates.

14. The semiconductor device package of claim 1, wherein the semiconductor package substrate is a first semiconductor package substrate that abuts the anisotropically conductive flexible film, further including:
a subsequent semiconductor package substrate that abuts the anisotropically conductive flexible film, wherein the semiconductive device is disposed on the subsequent semiconductor device substrate;
wherein the anisotropically conductive flexible film includes more than one anisotropic contact corridor that contact a single bond pad on at least one of the first and subsequent semiconductor package substrates; and
a heat sink seated on the subsequent semiconductor package substrate, wherein the heat sink also abuts the semiconductive device.

15. The semiconductor device package of claim 1, wherein the semiconductor package substrate is a first semiconductor package substrate, further including:
a subsequent semiconductor package substrate disposed below the first semiconductor package substrate;
a ribbon connector that contacts the anisotropically conductive flexible film, wherein the anisotropically conductive flexible film contacts the first semiconductor package substrate, and wherein the semiconductive device is disposed on the first semiconductor package substrate; and
a heat sink seated on the first semiconductor package substrate, wherein the heat sink also abuts the semiconductive device.

16. A process of assembling a semiconductor device package, comprising:
assembling an anisotropically conductive flexible film to at least one of:
a bond pad on a semiconductor package substrate;
a bond pad on a semiconductive device; and
a heat sink;
bonding the anisotropically conductive flexible film under conditions to form at least one of an electronic connection and a heat-transfer conductive channel.

17. The process of claim 16, wherein the semiconductor package substrate is a subsequent semiconductor package substrate, further including:
assembling a first semiconductor package substrate to the heat sink; and
assembling a shielding can to the semiconductor package substrate.

18. The process of claim 6, wherein the semiconductor package substrate is a first semiconductor package substrate, further including:
assembling a subsequent semiconductor package substrate to the anisotropically conductive flexible film, and wherein the semiconductive device is disposed on the first semiconductor package substrate opposite the anisotropically conductive flexible film; and
assembling a subsequent semiconductive device on the subsequent semiconductor package substrate, wherein a bilateral qualitative symmetry is configured with the first semiconductive device, the first semiconductor package substrate, the anisotropically conductive flexible film, the subsequent semiconductor package substrate, and the subsequent semiconductive device.

19. The process of claim 16, wherein the semiconductor package substrate is a subsequent semiconductor package substrate, and the semiconductive device is a subsequent semiconductive device disposed on the subsequent semiconductor package substrate, further including:
assembling a first semiconductive device on a first semiconductor package substrate;
wherein assembling the heat sink to abut the first semiconductive device and that is in direct contact with the anisotropically conductive flexible film, wherein the heat sink includes an insulated through-sink via, wherein the insulated through-sink via contacts the anisotropically conductive flexible film and the first semiconductor package substrate, and the anisotropically conductive flexible film contacts the subsequent semiconductive device; and
wherein assembling the subsequent semiconductive device to abut the anisotropically conductive flexible film.

20. The process of claim 16, wherein the semiconductive device is a first semiconductive device, further including:
assembling a subsequent semiconductive device to the first semiconductive device through the anisotropically conductive flexible film; and
wherein assembling the heat sink to abut the subsequent semiconductive device; and
wherein bonding the anisotropically conductive flexible film causes the semiconductor package substrate to be bonded to each of the heat sink and the subsequent semiconductive device.

21. The process of claim 16, wherein the anisotropically conductive flexible is a first anisotropically conductive flexible film, further including:
bonding a subsequent anisotropically conductive flexible film to form a package-on-package interconnect structure with the with the first anisotropically conductive flexible film;
seating the semiconductive device on the subsequent semiconductor package, wherein the first and subsequent anisotropically conductive flexible films support the subsequent semiconductor package above the first semiconductor package; and
seating a heat sink on the subsequent semiconductive device disposed on the subsequent semiconductor package.

22. The process of claim 16, wherein the semiconductor package substrate is a first semiconductor package substrate that is assembled to the anisotropically conductive flexible further including:
assembling a subsequent semiconductor package substrate to abut the anisotropically conductive flexible film, wherein the semiconductive device is disposed on the subsequent semiconductor device substrate; and
wherein bonding includes bonding the anisotropically conductive flexible film to include more than one anisotropic contact corridor contacting a single bond pad on at least one of the first and subsequent semiconductor package substrates.

23. The process of claim 16, wherein the semiconductor package substrate is a first semiconductor package substrate, further including:
bonding a subsequent semiconductor package substrate below the first semiconductor package substrate;
bonding a ribbon connector to contact the anisotropically conductive flexible film, wherein the anisotropically conductive flexible film contacts the first semiconductor package substrate, and wherein the semiconductive device is disposed on the first semiconductor package substrate; and
seating a heat sink on the first semiconductor package substrate, wherein the heat sink also abuts the semiconductive device.

24. A computing system, comprising:
an anisotropically conductive flexible film including a plurality of electrically conductive corridors disposed therein;
a semiconductor package substrate coupled to the anisotropically conductive flexible film;
a semiconductive device, wherein at least one of the semiconductor package substrate and the semiconductive device is in direct contact with the anisotropically conductive flexible film; and
wherein the semiconductive device is coupled with memory and a chipset.

25. The computing system of claim 24, further including:
a board to which the semiconductor package substrate is coupled; and
a heat sink seated on the board, wherein the heat sink also contacts the anisotropically, conductive flexible film.
